(19) United States
(12) Patent Application Publication
(10) Pub. No.: US 2026/0255621 A1
(43) Pub. Date: Aug. 27, 2026

(54) SEMICONDUCTOR DEVICE, CAPACITOR STRUCTURE, AND MANUFACTURING METHOD THEREOF

(71) Applicant: Fujian Jinhua Integrated Circuit Co., Ltd., Fujian (CN)

(72) Inventor: Xiaobing CHEN, Fujian (CN)

(73) Assignee: Fujian Jinhua Integrated Circuit Co., Ltd., Fujian (CN)

(21) Appl. No.: 19/539,093

(22) Filed: Feb. 13, 2026

(30) Foreign Application Priority Data
Feb. 21, 2025 (CN) 202510198907.1

(51) Int. Cl. H10D 1/68; H10D 1/00

(52) U.S. Cl. CPC H10D 1/716; H10D 1/714; H10D 1/041

(57) ABSTRACT

The present application provides a semiconductor device, a capacitor structure and a manufacturing method thereof, which are applied in the technical field of semiconductors. In the present application, by providing a semiconductor layer and an oxide layer in the capacitor structure, a new structure of the capacitor structure is proposed, and meanwhile the purpose of improving the efficiency and reliability of the semiconductor device is achieved.

### CROSS-REFERENCE TO RELATED APPLICATION

The present application claims priority to Chinese Patent Application No. 202510198907.1, filed on Feb. 21, 2025, which is hereby incorporated by reference in its entirety.

### TECHNICAL FIELD

The present application relates to the technical field of semiconductors, and in particular to a semiconductor device, a capacitor structure and a manufacturing method thereof.

### BACKGROUND

A dynamic random access memory (DRAM) is a volatile memory, including an array area composed of multiple memory cells, and a peripheral area composed of a control circuit. Each memory cell is composed of a transistor and a capacitor electrically connected to the transistor. The transistor controls the storage or release of charges in the capacitor, to achieve the purpose of storing data. The control circuit may address each memory cell via a word line (WL) and a bit line (BL) that span the array area and are electrically connected to each memory cell, so as to control the access to data in each memory cell. However, due to the limitations of process technologies, the existing dynamic random access memories still have many drawbacks, which need further improvement to effectively enhance the efficiency and reliability of the relevant memory components.

### SUMMARY

The purpose of the present application is to provide a semiconductor device, a capacitor structure and a manufacturing method thereof, so as to improve the efficiency and reliability of the semiconductor device and the capacitor structure.

In a first aspect, in order to solve the above technical problem, the present application provides a semiconductor device, including:
a substrate;
a plurality of capacitor structures, disposed on the substrate at an interval, the capacitor structures including: a lower electrode, a capacitor dielectric layer, and an upper electrode stacked in sequence;
a semiconductor layer disposed on the capacitor structures; and
an oxide layer between the upper electrode and the semiconductor layer.

In an implementation, the semiconductor device may further include:
a plurality of support structures, located between adjacent lower electrodes and including a plurality of support layers arranged at an interval along a vertical direction; and the capacitor dielectric layer and the upper electrode further extending to and covering a spacing between adjacent support layers of the support structure.

In an implementation, the lower electrode of each of the capacitor structures may include a cylindrical or columnar shape.

In an implementation, the upper electrode of the capacitor structures with the lower electrodes having the cylindrical shape can enclose to form a first gap, and the oxide layer is located on an inner surface of the first gap, and encloses to form a third gap.

In an implementation, the upper electrode in the spacing between the support layers can enclose to form a second gap, and the oxide layer is located on an inner surface of the second gap, and encloses to form a third gap.

In an implementation, the oxide layer is located on an inner surface of the first or second gap, and encloses to form a third gap.

In an implementation, the oxide layer may include a discontinuous oxide.

In an implementation, the discontinuous oxide may include a plurality of air gaps, and the plurality of air gaps divide the discontinuous oxide into a plurality of subsegments spaced apart to each other.

In an implementation, the oxide layer has a plurality of notches.

In an implementation, the semiconductor layer is located on the oxide layer, and fills the third gap.

In an implementation, the semiconductor layer is located on the oxide layer, and fills the plurality of notches or the plurality of air gaps.

In a second aspect, in order to solve the above technical problem, the present application further provides a capacitor structure, which may at least include:
a surrounding structure, including a semiconductor layer, an oxide layer, an upper electrode, a capacitor dielectric layer and a lower electrode in sequence from outside to inside, where the oxide layer physically contacts the semiconductor layer and the upper electrode.

In an implementation, the surrounding structure may further include the capacitor dielectric layer, the upper electrode, the oxide layer and the semiconductor layer inward from the lower electrode.

In an implementation, the lower electrode of the capacitor structure may include a cylindrical or columnar shape.

In a third aspect, in order to solve the above technical problem, the present application further provides a manufacturing method for a semiconductor device, including:
providing a substrate;
forming a plurality of capacitor structures disposed on the substrate at an interval, the capacitor structures including: a lower electrode, a capacitor dielectric layer, an upper electrode, and a semiconductor layer stacked in sequence; where at least one of the capacitor structures is provided with an oxide layer between the upper electrode and the semiconductor layer.

In an implementation, the manufacturing method for the semiconductor device may further include:
forming a plurality of support structures, located between adjacent lower electrodes and including a plurality of support layers arranged at an interval in a vertical direction; and the capacitor dielectric layer and the upper electrode further extending to and covering a spacing between adjacent support layers of the support structure.

In an implementation, the lower electrode of the capacitor structure may include a cylindrical or columnar shape.

In an implementation, the oxide layer may include a discontinuous oxide.

In an implementation, the discontinuous oxide may include a plurality of air gaps, and the plurality of air gaps may divide the discontinuous oxide into a plurality of subsegments.

In an implementation, the oxide layer may have a plurality of notches.

In an implementation, the semiconductor layer may be located on the oxide layer and fill the plurality of notches or the plurality of air gaps.

In the present application, the semiconductor device may include a plurality of capacitor structures, each of which includes a lower electrode, a capacitor dielectric layer, an upper electrode, and a semiconductor layer, which are stacked in sequence, and at least one of the capacitor structures is provided with an oxide layer between the upper electrode and the semiconductor layer, thereby proposing a new structure of the capacitor structure, and at the same time achieving the purpose of improving the efficiency and reliability of the semiconductor device and the capacitor structure.

### BRIEF DESCRIPTION OF DRAWINGS

The accompanying drawings are intended to provide further understanding of the present application, and form a part of the specification. The accompanying drawings are used to explain the present application together with the specific embodiments hereinafter, but do not constitute a limitation on the present application. In the accompanying drawings:

FIG. 1-FIG. 4 are structural schematic diagrams of a semiconductor device during its manufacturing process according to a first embodiment of the present application.

FIG. 5-FIG. 8 are structural schematic diagrams of a semiconductor device during its manufacturing process according to a second embodiment of the present application.

FIG. 9-FIG. 10 are structural schematic diagrams of a semiconductor device during its manufacturing process according to a third embodiment of the present application.

FIG. 11-FIG. 12 are structural schematic diagrams of a semiconductor device during its manufacturing process according to a forth embodiment of the present application.

Where the reference signs are as follows:
100—Substrate, 110—Support structure, 111—First support layer, 113—Second support layer, 115—Third support layer, 120—Capacitor structure, 121—Lower electrode, 122 Capacitor dielectric layer, 123—Upper electrode, 130—Oxide layer, 140—Semiconductor layer, 101—First gap, 102—Second gap, 103—Third gap, 104—Air gap, 105—Notch, 131 Subsegment.

In the accompanying drawings, the same components use the same reference signs, and the accompanying drawings are not drawn according to an actual scale.

### DESCRIPTION OF EMBODIMENTS

In order to make the technical solutions and the advantages of the embodiments of the present application clearer, the technical solutions of the present application will be further illustrated in detail in combination with the accompanying drawings and the embodiments. Although exemplary embodiments of the present application have shown in the drawing, it should be understood that the present application can be implemented in various forms and should not be limited by the embodiments described herein. On the contrary, these embodiments are provided to enable a more thorough understanding of the present application and to fully convey the scope of the present application to those skilled in the art.

In the following paragraphs, the present application is described more specifically by way of examples with reference to the accompanying drawings. According to the following description and claims, the advantages and characteristics of the present application will be clearer. It should be noted that all of the accompanying drawings are presented in a highly simplified form, and use imprecise scale, only for the purpose of conveniently and clearly assisting in the explanation of the embodiments of the present application. It can be understood that the terms “on . . . ”, “above . . . ” and “over . . . ” used in the present application should be interpreted in the broadest manner so that “on . . . ” not only means that it is provided “on” something, without an intermediate feature or layer therebetween (i.e., directly on something), but also means that it is provided “on” something, with an intermediate feature or layer therebetween.

Furthermore, for ease of description, spatially relative terms such as “on . . . ”, “above . . . ”, “over . . . ”, “upon” and “upper part” may be used herein to describe the relationship of one element or feature to another element or feature as illustrated in the drawings. In addition to the orientations depicted in the accompanying drawings, the spatially relative terms are intended to cover different orientations of a device during use or operation. The device can be oriented in other ways (rotated by 90 degrees or in other orientations) and the spatially relative terms used herein may likewise be interpreted accordingly.

In the embodiments of the present application, the terms “first”, “second”, etc. are used to distinguish similar objects, rather than used to describe a specific order or sequence. It should be noted that the technical solutions recorded in the embodiments of the present application may be combined arbitrarily without conflict.

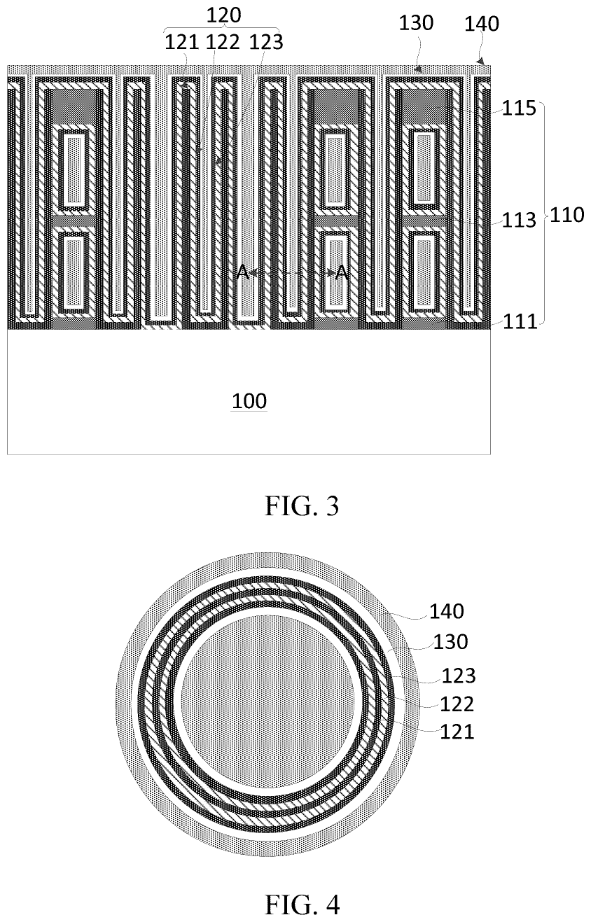

Please referring to FIG. 3 and FIG. 4, FIG. 3 is a sectional schematic diagram of a semiconductor device in a first embodiment of the present application, and FIG. 4 is a top view of the semiconductor device shown in FIG. 3 along an AA line. The semiconductor device of the present application can be used to manufacture a dynamic random access memory (DRAM), and the present application can also be applied to other types of memories without departing from the spirit of the present application.

As shown in FIG. 3 and FIG. 4, the semiconductor device includes a substrate 100, which may be, for example, a silicon substrate, a silicon-containing substrate (such as SiC, SiGe), or a silicon-on-insulator substrate, or a substrate composed of other suitable materials, without being limited thereto. Along a direction parallel to a surface of the substrate 100 (hereinafter referred to as a horizontal direction), a plurality of capacitor structures 120 are disposed on the substrate 100 at an interval. Specifically, the capacitor structures 120 may include a lower electrode 121, a capacitor dielectric layer 122, an upper electrode 123, and a semiconductor layer 140, which are stacked in sequence, and an oxide layer 130 is further provided between the upper electrode 123 and the semiconductor layer 140 in at least one capacitor structure 120 of the plurality of capacitance structures 120.

It should be understood that the substrate 100 can be further formed with a bit line structure, a sidewall structure, a contact structure, a connection pad structure and other components (not shown), without being limited thereto.

Specifically, in a first embodiment of the present application, the lower electrode 121 of the capacitor structure 120 includes a cylindrical shape, and a plurality of lower electrodes 121 of the plurality of capacitor structures 120 are disposed on the substrate 100 at an interval along the horizontal direction, and a support structure 110 is further provided between adjacent lower electrodes 121. The capacitor dielectric layer 122, the upper electrode 123 and the oxide layer 130 of the capacitor structure 120 cover conformally on the plurality of lower electrodes 121 with the cylindrical shape, and the semiconductor layer 140 fills a gap within the oxide layers 130 in the plurality of capacitor structures 120. Furthermore, the support structure 110 may include a plurality of support layers arranged in sequence from bottom to top, such as a first support layer 111, a second support layer 113 and a third support layer 115 arranged in sequence from bottom to top along a vertical direction. The capacitor dielectric layer 122, the upper electrode 123, the oxide layer 130, and the semiconductor layer 140 in the plurality of capacitor structures 120 further extend to and cover a spacing between adjacent support layers in the plurality of support structures 110, such as the spacing between the first support layer 111 and the second support layer 113, the spacing between the second support layer 113 and the third support layer 115, without being limited thereto.

In an embodiment, the materials of the lower electrode 121 and the upper electrode 123 may include titanium nitride, tantalum nitride, SiGe, a combination of the above materials, or other suitable multi-layered conductive materials, without being limited thereto. The capacitor dielectric layer 122 may include a material layer with high dielectric constant, such as TaOO, TaAlO, TaON, AlO, AlSiO, HfO, HfSiO, ZrO, ZrSiO, TiO, TiAlO, BST((Ba, Sr)TiO), STO(SrTiO), BTO(BaTiO), PZT(Pb(Zr,Ti)O), (Pb,La)(Zr,Ti)O, Ba(Zr,Ti)OO, Sr(Zr,Ti)O, a combination of the above materials, or other suitable dielectric materials, without being limited thereto. The material of the oxide layer 130 may be an insulating material, such as oxides or nitrides, without being limited thereto. The material of the semiconductor layer 140 may be crystalline silicon (crystalline silicon), poly silicon (poly silicon), amorphous silicon (amorphous silicon), doped silicon, silicon germanium (SiGe), or other suitable semiconductor materials, without being limited thereto. The materials of the first support layer 111, the second support layer 113 and the third support layer 115 in the support structure 110 may be an oxide material, such as silicon oxide, boro-phospho-silicate-glass (BPSG), without being limited thereto.

The general technician in the technical field to which the present application pertains should easily understand that the semiconductor device of the present application may also have other forms, but is not limited to the aforementioned one on the premise that it can meet the actual product requirements. Other embodiments or variations of the semiconductor device of the present application are further described below. In order to simplify the description, the following description mainly describes in detail the differences between the embodiments, without repeating the same content. In addition, the same components in embodiments of the present application are marked with the same reference signs, to facilitate mutual comparison between the embodiments.

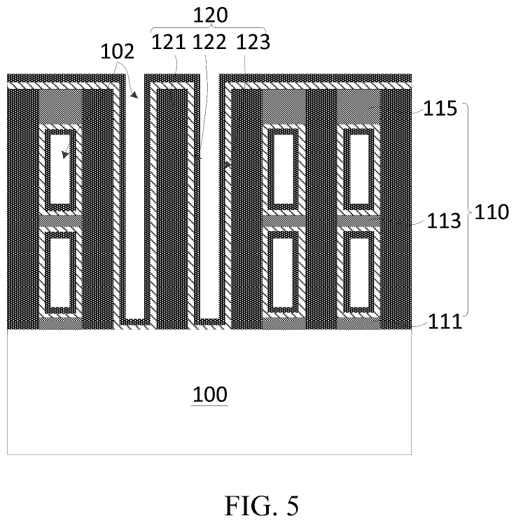

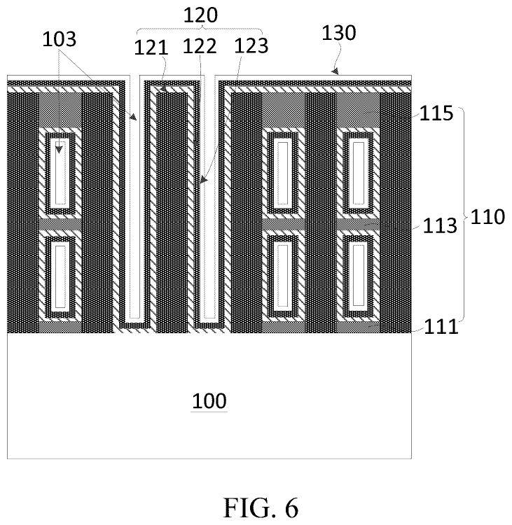

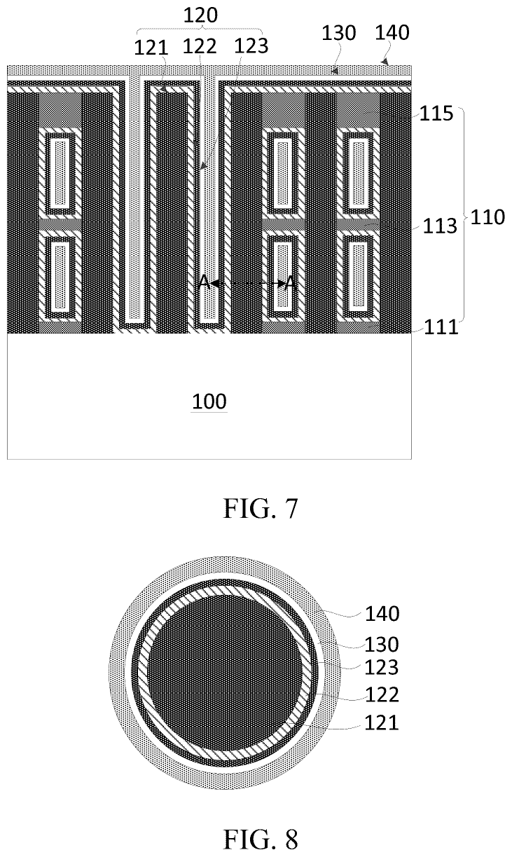

Please referring to FIG. 7 and FIG. 8, FIG. 7 is a sectional schematic diagram of a semiconductor device in a second embodiment of the present application, and FIG. 8 is a top view of the semiconductor device shown in FIG. 7 along an AA line. As shown in FIG. 7 and FIG. 8, the structure of the semiconductor device in the present embodiment is generally the same as that of the semiconductor device in the aforementioned first embodiment, such as the semiconductor device also includes a substrate 100 and a plurality of capacitor structures 120 disposed on the substrate 100, and the capacitor structures 120 may also specifically include a lower electrode 121, a capacitor dielectric layer 122, an upper electrode 123, and a semiconductor layer 140, which are stacked in sequence, at least one capacitor structure 120 of the plurality of capacitor structures 120 is further provided with an oxide layer 130 between the upper electrode 123 and the semiconductor layer 140, and the like, without repeating the same content here. The main differences between the semiconductor device of the present embodiment and the semiconductor device of the above first embodiment are that: the lower electrode 121 of the capacitor structure 120 in the present embodiment includes a columnar shape. Under this setting, the capacitor dielectric layer 122, the upper electrode 123 and the oxide layer 130 of each capacitor structure 120 are conformally formed in sequence on surfaces of the plurality of lower electrodes 121 with the columnar shape. That is, the upper electrode 123 of each capacitor structure 120 is not provided with a first gap 101, as shown in FIG. 5, in the present embodiment. Similarly, the subsequently formed oxide layer 130 in the capacitor structure 120 is not provided with a third gap 103, as shown in FIG. 6.

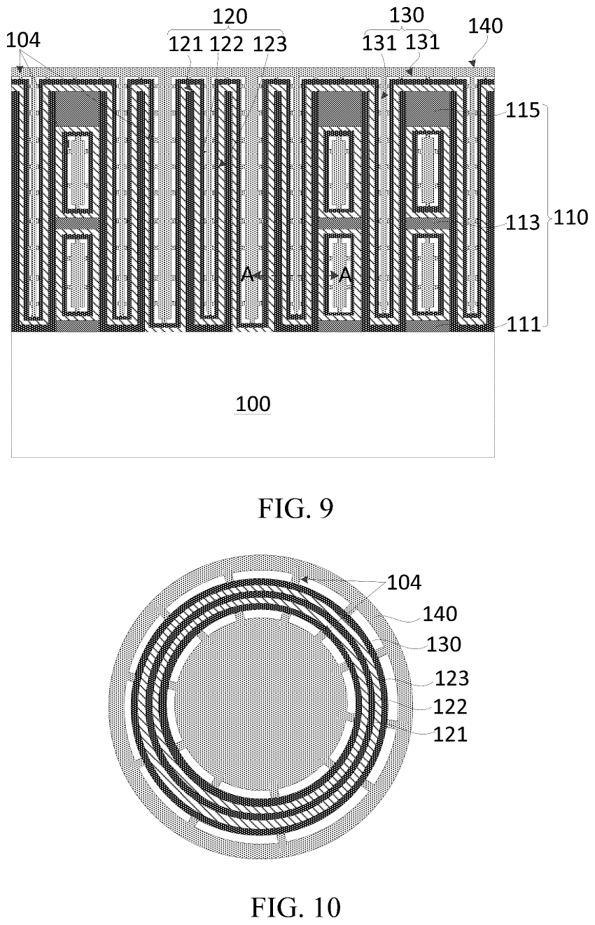

Please referring to FIG. 9 and FIG. 10, FIG. 9 is a sectional schematic diagram of a semiconductor device in a third embodiment of the present application, and FIG. 10 is a top view of the semiconductor device shown in FIG. 9 along an AA line. As shown in FIG. 9 and FIG. 10, the structure of the semiconductor device in the present embodiment is generally the same as that of the semiconductor device in the aforementioned first or second embodiment, such as the semiconductor device also includes a substrate 100 and a plurality of capacitor structures 120 disposed on the substrate 100, and the capacitor structures 120 may also specifically include a lower electrode 121, a capacitor dielectric layer 122, an upper electrode 123, and a semiconductor layer 140, which are stacked in sequence, at least one capacitor structure 120 of the plurality of capacitor structures 120 is further provided with an oxide layer 130 between the upper electrode 123 and the semiconductor layer 140, and the like, without repeating the same content here. The main differences between the semiconductor device of the present embodiment and the semiconductor device of the first or second embodiment are that: in the present embodiment, the oxide layer 130 in the capacitor structure 120 and in the spacing between adjacent support layers of the support structure 110 may be a discontinuous oxide (such as discontinuous silica). Specifically, the oxide layer 130, which is the discontinuous oxide, may include a plurality of air gaps 104, and the plurality of air gaps 104 divide the oxide layer 130 (i.e., the discontinuous oxide) into a plurality of subsegments 131 spaced apart to each other. In this way, the semiconductor layer 140 subsequently formed not only fills the third gap 103 enclosed by the oxide layer 130, but also further fills the plurality of air gaps 104 within the oxide layer 130, so that the semiconductor layer 140 passes through the oxide layer 130 by the air gaps 104 and directly contacts the upper electrode 123 within the capacitor structure 120 or the supporting structure 110. In an embodiment, widths or depths of the plurality of air gaps 104 along the horizontal or vertical direction may be the same or different, and the interval between adjacent air gaps 104 may be the same or different.

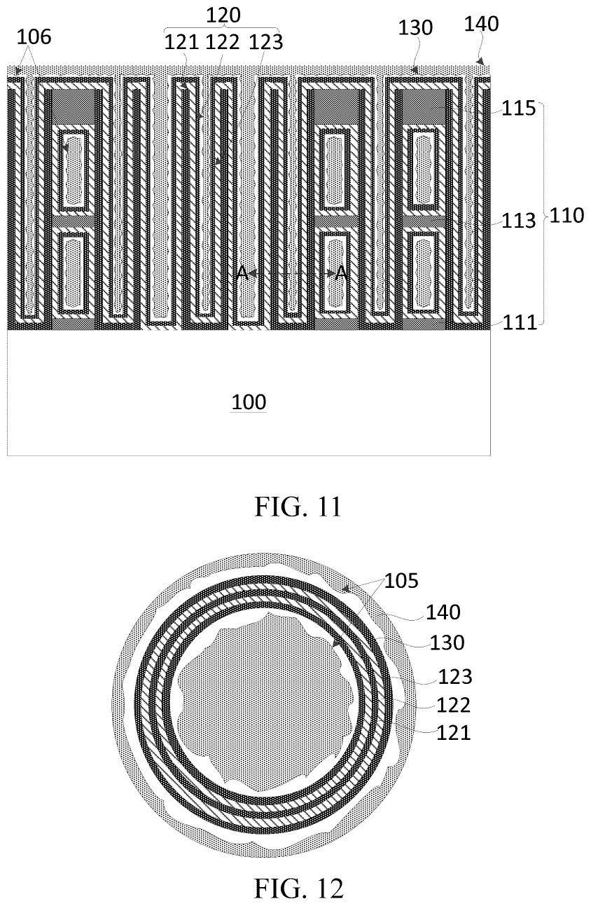

Please referring to FIG. 11 and FIG. 12, FIG. 11 is a sectional schematic diagram of a semiconductor device in a fourth embodiment of the present application, and FIG. 12 is a top view of the semiconductor device shown in FIG. 11 along an AA line. As shown in FIG. 11 and FIG. 12, the structure of the semiconductor device in the present embodiment is generally the same as the structures of the semiconductor devices in the aforementioned first to third embodiments, such as the semiconductor device also includes a substrate 100 and a plurality of capacitor structures 120 disposed on the substrate 100, the capacitor structures 120 may specifically include a lower electrode 121, a capacitor dielectric layer 122, an upper electrode 123, and a semiconductor layer 140, which are stacked in sequence, at least one capacitor structure 120 of the plurality of capacitor structures 120 is further provided with an oxide layer 130 between the upper electrode 123 and the semiconductor layer 140, and the like, without repeating the same content here. The main differences between the semiconductor device of the present embodiment and the semiconductor devices of the first to third embodiments are that: in the present embodiment, the oxide layer 130 in the capacitor structure 120 and in the spacing between adjacent support layers of the support structure 110 may have a plurality of notches 105, and the oxide layer 130 is residual at the bottom of each of the plurality of notches 105. In this way, the plurality of notches 105 causes a surface of the oxide layer 130 to be uneven and wavy, and the semiconductor layer 140 formed subsequently not only fills the third gap 103 enclosed by the oxide layer 130, but also further fills the plurality of notches 105 within the oxide layer 130; but in the present embodiment, the semiconductor layer 140 only contacts directly the oxide layer 130. In an embodiment, widths, depths, or shapes of the plurality of notches 105 along the horizontal or vertical direction may be the same or different, and the interval between adjacent notches 105 may be the same or different.

In addition, based on the above, a fifth embodiment of the present application further provides a capacitor structure. As shown in FIGS. 4, 8, 10 or 12, the capacitor structure may specifically include:
a surrounding structure, including a semiconductor layer 140, an oxide layer 130, an upper electrode 123, a capacitor dielectric layer 122 and a lower electrode 121 in sequence from outside to inside, where the oxide layer 130 physically contacts the semiconductor layer 140 and the upper electrode 123.

In an embodiment, the surrounding structure also includes the capacitor dielectric layer 122, the upper electrode 123, the oxide layer 130 and the semiconductor layer 140 inward from the lower electrode 121. Moreover, the lower electrode 121 of the capacitor structure includes a cylindrical or columnar shape, without being limited thereto. Furthermore, the oxide layer 130 may include a discontinuous oxide. Exemplarily, the discontinuous oxide may include a plurality of air gaps 104, so that the oxide layer 130 (i.e., the discontinuous oxide) are divided into a plurality of subsegments 131 spaced apart to each other by the plurality of air gaps 104. Or, the oxide layer 130 has a plurality of notches 105, and the semiconductor layer 140 fills the third gap 103 enclosed by the oxide layer 130, the plurality of air gaps 104 or the plurality of notches 105, without being limited thereto.

It should be understood that the “conformally” in the present application refers to constructing a continuous structural shape by utilizing the similarity and correlation in morphology between two or more shapes.

In order to enable the general technician in the technical field to which the present application pertains to easily understand the semiconductor device in the embodiments of the present application, an embodiment of the present application further provides a manufacturing method for the semiconductor device. The manufacturing method for the semiconductor device proposed by the present application is further illustrated hereinafter in combination with respective structural schematic diagrams during the manufacturing process using the manufacturing method.

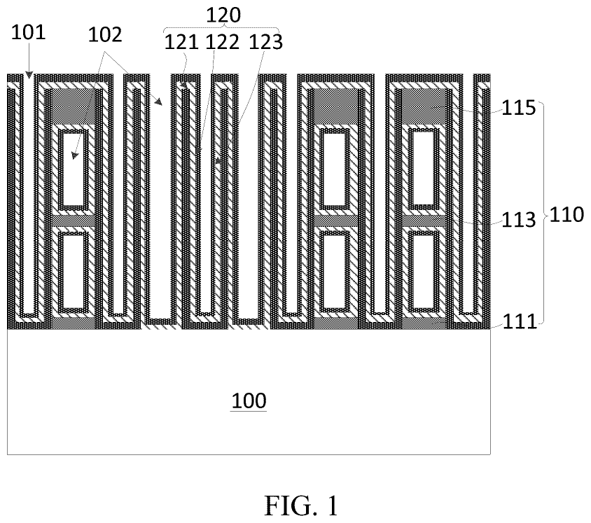

FIG. 1-FIG. 4 are structural schematic diagrams of the semiconductor device during its manufacturing process using the manufacturing method according to the first embodiment of the present application.

Refer to FIG. 1, formation of the capacitor structure 120 with the lower electrode 121 having the cylindrical shape is, for example, firstly providing a substrate 100 (the material thereof is, for example, a silicon substrate); then forming a multi-layered structure of the support structure 110 on the substrate 100 by using a deposition process, the multi-layered structure being such as the first support layer 111 (the material thereof is, for example, silicon oxide or boro-phospho-silicate-glass), a first sacrificial layer (not shown), the second support layer 113 (the material thereof is, for example, silicon oxide or boro-phospho-silicate-glass), a second sacrificial layer (not shown), and the third support layer 115 (the material thereof is, for example, silicon oxide or boro-phospho-silicate-glass); then forming a plurality of through holes (not shown) within the multi-layered structure of the support structure 110; conformally forming a lower electrode material layer (the material thereof is, for example, titanium nitride, tantalum nitride or SiGe) in the plurality of through holes by using a deposition process such as at least one of a physical vapor deposition process, a chemical vapor deposition process and an atomic layer deposition process, that is, forming a plurality of lower electrodes 121 on the substrate 100; and then, after removing part of the support structures 110 by using a photolithography and etching process (such as a dry etching process and/or a wet etching process), further conformally forming the capacitor dielectric layer 122 (the material thereof is, for example, a material layer with a high dielectric constant) and the upper electrode 123 (the material thereof is, for example, titanium nitride, tantalum nitride or SiGe) by using a deposition process.

It should be understood that under this setting, the upper electrode 123 formed conformally encloses to form a first gap 101 within each capacitor structure 120, and encloses to form a second gap 102 within the spacing between adjacent support layers of the support structure 110.

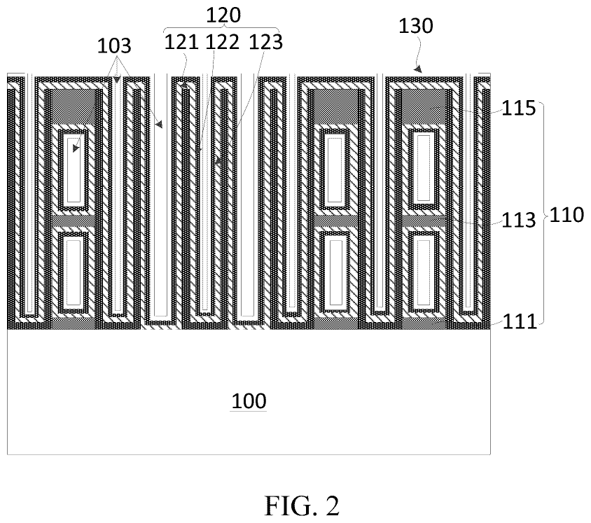

Please referring to FIG. 2, next, the oxide layer 130 (the material thereof is, for example, oxide or nitride) is conformally formed by using a deposition process, such as a chemical vapor deposition process. In this way, the oxide layer 130 formed conformally is specifically located on the upper electrode 123, and is located on the inner surface of the first gap 101 or the second gap 102, and further the oxide layer 130 encloses to form a third gap 103 on the upper electrode 123 on the substrate 100.

Please referring to FIG. 3 or FIG. 4, finally, the semiconductor layer 140 (the material thereof is a semiconductor material, such as monocrystalline silicon, polysilicon, etc.), which fills the third gap 103 and the top surface of which is higher than the top surface of the oxide layer 130, is formed by using a deposition process, such as a chemical vapor deposition process.

Obviously, the semiconductor device formed by the manufacturing method provided in the embodiment of the present application may include a substrate 100 and a plurality of spaced capacitor structures 120 disposed on the substrate 100 at an interval. Specifically, the capacitor structures 120 include: a lower electrode 121, a capacitor dielectric layer 122, an upper electrode 123, and a semiconductor layer 140, which are stacked in sequence, where at least one of the capacitor structures 120 is provided with an oxide layer 130 between the upper electrode 123 and the semiconductor layer 140, and the capacitor dielectric layer 122 and the upper electrode 123 further extend to and cover the spacing between adjacent support layers of the support structure 110.

Furthermore, in order to enable the general technician in the technical field to which the present application pertains to easily understand the semiconductor device and capacitor structure in the second embodiment of the present application, the present application further provides a manufacturing method for the semiconductor device in the second embodiment. FIG. 5-FIG. 8 are structural schematic diagrams of the semiconductor device during its manufacturing process using the manufacturing method according to the second embodiment of the present application. Since the semiconductor device in the second embodiment of the present application is generally the same as that in the first embodiment, the manufacturing method for the corresponding components and/or device is also the same. The part of the manufacturing method in the second embodiment of the present application that is the same as that in the first embodiment will not be repeated below, and only the differences in their manufacturing methods will be illustrated.

Specifically, as shown in FIG. 5, in the process of conformally forming the lower electrode material layer (the material thereof is, for example, titanium nitride, tantalum nitride or SiGe) in the plurality of through holes by using the deposition process (such as at least one of a physical vapor deposition process, a chemical vapor deposition process and an atomic layer deposition process) to form the plurality of lower electrodes 121 on the substrate 100, the shape of the lower electrodes 121 formed within the through holes in the second embodiment of the present application differs from the shape of the lower electrodes 121 in the first embodiment. Specifically, the lower electrodes 121 of the capacitor structures 120 in the second embodiment of the present application include a columnar shape. Under this setting, the part of the upper electrode 123 formed subsequently and conformally within the capacitor structure 120 does not enclose to form the first gap 101; instead, it only encloses to form the second gap 102 within the spacing between adjacent support layers of the support structure 110.

Furthermore, in order to enable the general technician in the technical field to which the present application pertains to easily understand the semiconductor device in the third embodiment of the present application, the present application further provides a manufacturing method for the semiconductor device in the third embodiment. Since the semiconductor device in the third embodiment of the present application is generally the same as that in the aforementioned first or second embodiment, the manufacturing method for the corresponding components and/or device is also the same. The part of the manufacturing method in the third embodiment of the present application that is the same as that in the first or second embodiment will not be repeated below, and only the differences in their manufacturing methods will be illustrated.

Specifically, as shown in FIG. 9, the main differences between the manufacturing method in the third embodiment of the present application and the manufacturing method in the first or second embodiment are that: after conformally forming the oxide layer 130 by the deposition process, forming a plurality of air gaps 104, widths and/or depths of which are the same or different, within the oxide layer 130 by using an etching process (such as a dry etching process), so as to expose a part of the top surface of the upper electrode 123 located in the capacitor structure 120 or the support structure 110, without being limited thereto.

Furthermore, in order to enable the general technician in the technical field to which the present application pertains to easily understand the semiconductor device in the fourth embodiment of the present application, the present application further provides a manufacturing method for the semiconductor device in the fourth embodiment. Since the semiconductor device in the fourth embodiment of the present application is generally the same as those in the aforementioned first to third embodiments, the manufacturing method for the corresponding components and/or device is also the same. The part of the manufacturing method in the fourth embodiment of the present application that is the same as those in the first to third embodiments will not be repeated below, and only the differences in their manufacturing methods will be illustrated.

Specifically, as shown in FIG. 11, the main differences between the manufacturing method in the fourth embodiment of the present application and the manufacturing methods in the first to third embodiments are that: after conformally forming the oxide layer 130 by the deposition process, forming a plurality of notches 105, widths, depths and/or shapes of which are the same or different, within the oxide layer 130 by using an etching process (such as a dry etching process), and the notches 105 do not penetrate the oxide layer 130, without being limited thereto.

It should be understood that the capacitor structure 120 in the fifth embodiment of the present application is the capacitor structure 120 corresponding to the semiconductor device in any one of the first to fourth embodiments above, so the manufacturing method for the capacitor structure 120 in the fifth embodiment is specifically described in the manufacturing method corresponding to the semiconductor device in any one of the first to fourth embodiments above, and will not be repeated here.

In summary, the plurality of capacitor structures in the present application each include a lower electrode, a capacitor dielectric layer, an upper electrode, and a semiconductor layer, which are stacked in sequence, and at least one of the capacitor structures is further provided with an oxide layer between the upper electrode and the semiconductor layer, thereby proposing a new structure of the capacitor structure, and at the same time achieving the purpose of improving the efficiency and reliability of the semiconductor device.

The above are only better embodiments of the present application and are not intended to limit the protection scope of the present application. Any modifications, equivalent replacements, improvements, etc. made within the spirit and principles of the present application are included in the protection scope of the present application.

What is claimed is:

1. A semiconductor device, comprising:
a substrate;
a plurality of capacitor structures disposed on the substrate at an interval, wherein the capacitor structures comprise: a lower electrode, a capacitor dielectric layer, and an upper electrode stacked in sequence;
a semiconductor layer disposed on the capacitor structures; and
an oxide layer between the upper electrode and the semiconductor layer.

2. The semiconductor device according to claim 1, further comprising:
a plurality of support structures, located between adjacent lower electrodes and including a plurality of support layers arranged at an interval along a vertical direction; and the capacitor dielectric layer and the upper electrode further extending to and covering a spacing between adjacent support layers of the support structure.

3. The semiconductor device according to claim 1, wherein the lower electrode of each of the capacitor structures comprises a cylindrical or columnar shape.

4. The semiconductor device according to claim 3, wherein the upper electrode of the capacitor structures with the lower electrodes having the cylindrical shape encloses to form a first gap, and the oxide layer is located on an inner surface of the first gap, and encloses to form a third gap.

5. The semiconductor device according to claim 2, wherein the upper electrode in the spacing between the support layers encloses to form a second gap, and the oxide layer is located on an inner surface of the second gap, and encloses to form a third gap.

6. The semiconductor device according to claim 1, wherein the oxide layer comprises a discontinuous oxide.

7. The semiconductor device according to claim 6, wherein the discontinuous oxide comprises a plurality of air gaps, and the plurality of air gaps divide the discontinuous oxide into a plurality of subsegments spaced apart to each other.

8. The semiconductor device according to claim 1, wherein the oxide layer has a plurality of notches.

9. The semiconductor device according to claim 7, wherein the semiconductor layer is located on the oxide layer, and fills the plurality of air gaps.

10. The semiconductor device according to claim 8, wherein the semiconductor layer is located on the oxide layer, and fills the plurality of notches.

11. A capacitor structure, comprising:
a surrounding structure, comprising a semiconductor layer, an oxide layer, an upper electrode, a capacitor dielectric layer and a lower electrode in sequence from outside to inside, wherein the oxide layer physically contacts the semiconductor layer and the upper electrode.

12. The capacitor structure according to claim 11, wherein the surrounding structure further comprises the capacitor dielectric layer, the upper electrode, the oxide layer and the semiconductor layer inward from the lower electrode.

13. The capacitor structure according to claim 11, wherein the lower electrode of the capacitor structure comprises a cylindrical or columnar shape.

14. A manufacturing method for a semiconductor device, comprising:
providing a substrate;
forming a plurality of capacitor structures disposed on the substrate at an interval, the capacitor structures comprising: a lower electrode, a capacitor dielectric layer, an upper electrode, and a semiconductor layer stacked in sequence; wherein at least one of the capacitor structures is provided with an oxide layer between the upper electrode and the semiconductor layer.

15. The manufacturing method for the semiconductor device according to claim 14, further comprising: forming a plurality of support structures, located between adjacent lower electrodes and comprising a plurality of support layers arranged at an interval in a vertical direction; and the capacitor dielectric layer and the upper electrode further extending to and covering a spacing between adjacent support layers of the support structure.

16. The manufacturing method for the semiconductor device according to claim 14, wherein the oxide layer comprises a discontinuous oxide.

17. The manufacturing method for the semiconductor device according to claim 16, wherein the discontinuous oxide comprises a plurality of air gaps, and the plurality of air gaps divide the discontinuous oxide into a plurality of subsegments.

18. The manufacturing method for the semiconductor device according to claim 14, wherein the oxide layer has a plurality of notches.

19. The manufacturing method for the semiconductor device according to claim 17, wherein the semiconductor layer is located on the oxide layer, and fills the plurality of air gaps.

20. The manufacturing method for the semiconductor device according to claim 18, wherein the semiconductor layer is located on the oxide layer, and fills the plurality of notches.
